(19) United States
(12) Patent Application Publication
(10) Pub. No.: US 2013/0092999 A1
(43) Pub. Date: Apr. 18, 2013

(54) NONVOLATILE STORAGE DEVICE

(71) Applicant: Motoki FUJII, Tokyo (JP)

(72) Inventor: Motoki FUJII, Tokyo (JP)

(73) Assignee: ELPIDA MEMORY, INC., Tokyo (JP)

(21) Appl. No.: 13/612,223

(22) Filed: Sep. 12, 2012

(30) Foreign Application Priority Data
Oct. 17, 2011 (JP) 2011-227999

(51) Int. Cl. H01L 29/792

(52) U.S. Cl. 257/326; 257/E29.309

(57) ABSTRACT

A nonvolatile storage device includes a tunnel insulating film disposed on a surface of a semiconductor substrate and a charge trap layer disposed in contact with an upper surface of the tunnel insulating film. The charge trap layer includes a second charge trap film disposed in contact with the upper surface of the tunnel insulating film and a first charge trap film disposed in contact with an upper surface of the second charge trap film.

This application is based upon and claims the benefit of priority from Japanese Patent Application No. 2011-227999 filed on Oct. 17, 2011, the disclosure of which are incorporated herein in its entirety by reference.

### BACKGROUND OF THE INVENTION

1. Field of the Invention

The present invention relates to a nonvolatile storage device including a charge trap layer.

2. Description of the Related Art

A nonvolatile flash memory is widely used as one type of semiconductor memory. Storage cell methods used in a flash memory include a floating gate method and a charge trap method. A representative gate structure in the charge trap method is an MNOS structure. MNOS stands for a vertical structure of a gate that is made of a control gate electrode (M), a silicon nitride film (N), a tunnel silicon oxide film (O), and a silicon substrate (S). A frequently used MNOS structure is an SONOS structure. This SONOS structure is produced by forming the control gate electrode with a silicon film (S), sandwiching a silicon oxide film (O) between the control gate electrode and the silicon nitride film, and forming the tunnel silicon oxide film between the silicon nitride film and the silicon substrate. JP2001-57093A discloses a method for manufacturing a nonvolatile memory that includes a charge trap layer formed of a monolayer and has compatibility with a logic IC. JP2010-10323A discloses a nonvolatile memory device that includes a charge trap layer formed of a monolayer and has a multivalued memory capability.

A JPMNOS structure, which uses a charge trapping characteristic specific to a silicon nitride film, is basically configured to have charge traps distributed in the insulating film. The discharging probability of trapped charge is therefore lower than that in the floating gate method, in which a conductor is used. That is, the amount of leakage current decreases. As a result, the tunnel silicon oxide film (hereinafter referred to as tunnel oxide film) does not need to be thick in order to prevent leakage current and can be a very thin film having a thickness of about 2 nm, which is believed to be advantageous in low-voltage operation and high-speed operation.

In recent years, there have been studies on further improvement in the charge trapping characteristic by replacing the stoichiometric silicon nitride film (Si₃N₄) with a silicon-rich nitride film (hereinafter abbreviated to SiRN) containing a larger amount of Si. A silicon nitride film (hereinafter referred to as SiN) produced in a thermochemical reaction process composes typically a network made of stoichiometric Si₃N₄, and the entirety of the resultant film is a perfect insulating film. In contrast, SiRN is produced by forcing Si dots to be introduced into an Si-N network, which is an insulating film, and the Si dots hold charge. SiRN is believed to have an improved charge trapping characteristic, as compared with a case where a silicon nitride film, the entirety of which is an insulating film, traps charge.

To form an SiRN film, a batch-type vertical film formation apparatus is used. JP2000-26973A and JP2005-12168A disclose batch-type vertical film formation apparatus.

FIG. 1 schematically shows a batch-type vertical film formation apparatus. The film formation apparatus includes cylindrical film formation chamber 2 including ports 3 therein, as shown in FIG. 1. Ports 3 are capable of supporting several tens of semiconductor substrates and used to place several tens of semiconductor substrates 4 at fixed intervals in the vertical direction. Film formation is performed while ports 3 are rotating. Heater 1 is provided around the outer surface of film formation chamber 2 and capable of heating semiconductor substrates 4 in film formation chamber 2. The film formation chamber 2 is so controlled that the internal pressure is fixed by exhausting internal gas through nozzle 6. A raw material gas is injected through nozzle 5 into film formation chamber 2 and then diffused therein to cause, for example, a thermal decomposition reaction, whereby a desired film is formed on each semiconductor substrate 4. The raw material gas that has not reacted is exhausted through nozzle 6. A plurality of nozzles 5 and 6 may be provided in accordance with the types of raw material gas and exhaust gas, although FIG. 1 shows only one nozzle 5 and only one nozzle 6.

To form the SiN film and the SiRN film described above, dichlorosilane (SiH₂Cl₂: hereinafter referred to as DCS) and ammonia (NH₃) are used as the raw material gases. To produce the SiN film, the amount of ammonia supplied to the film formation chamber is typically set to be sufficiently greater than (five times or more in terms of molar quantity) the amount of DCS supplied to the film formation chamber. Si atoms that contribute to the film formation thus all react with the ammonia to form SiN. Although excess ammonia is present in the film formation chamber, ammonia decomposition products themselves are gaseous hydrogen and nitrogen. Accordingly, ammonia that has not reacted does not contribute to the film formation, and are exhausted directly out of the reaction chamber. The SiN film produced by the thermochemical reaction process therefore cannot be a nitrogen-rich silicon nitride film.

On the other hand, to produce an SiRN film, the amount of supplied DCS is conversely set to be greater than the amount of supplied ammonia (ammonia/DCS ratio is smaller than 5 in terms of molar quantity), unlike the case where an SiN film is formed. As a result, although the amount of DCS agrees with the amount of supplied ammonia reacts with ammonia to form SiN, and solid Si in the excess DCS deposits and is introduced into the SiN film. An SiRN film is thus formed.

To manufacture a nonvolatile flash memory that is an object of the present application, it is necessary to form an SiRN film on a tunnel oxide film formed on a surface of a silicon substrate. The present inventor attempted to form an SiRN film on a semiconductor substrate on which a tunnel oxide film had been formed by using a batch-type vertical film formation apparatus. The present inventor found that the film thickness distribution of the SiRN film in the plane of the substrate greatly varied as compared with a case where an SiN film was formed. The variation in the film thickness distribution of the SiRN film leads to variation in the charge trapping characteristic of a nonvolatile storage device, which is not preferable. The variation in the thickness of the SiRN film as a charge trap layer is preferably believed to be smaller than or equal to 1.5 nm in the plane of a semiconductor substrate having a diameter of 300 mm, more preferably smaller than or equal to 1 nm.

In view of the problem described above, the present inventor considered how the phenomenon described above occurs as follows:

A method for forming an SiRN film will first be described. An SiRN film is formed by using a stepping film formation process. That is, the film is formed by placing a plurality of semiconductor substrates on each of which a tunnel oxide film has been formed in a film formation chamber of a vertical film formation apparatus and then repeating a single cycle formed of the following first to fourth steps multiple times until a desired film thickness is achieved, with a predetermined temperature, for example, 630° C., maintained:

(a1) supplying DCS (first raw material gas), which works as an Si raw material, and adsorbing deposited Si onto the tunnel oxide film (first step),
(a2) exhausting DCS (first raw material gas) that has not reacted out of the film formation chamber (second step),
(a3) supplying ammonia (second raw material gas), which works as a nitriding raw material, and nitriding the adsorbed Si to convert Si into SiN (third step), and
(a4) exhausting ammonia (second raw material gas) that has not reacted out of the film formation chamber (fourth step).

Among the series of steps described above, in the third step of supplying ammonia, the amount of supplied ammonia is reduced in order not to nitride all the adsorbed Si. As a result, part of the adsorbed Si is nitrided and converted into SiN, and Si that has not been nitrided remains in the form of Si. When the film formation is finished, the film contains the Si that has not been nitrided and forms an SiRN film. The Si/N ratio in the SiRN film can be changed by controlling the amount of supplied ammonia.

Next, the variation of the film thickness distribution of the SiRN film will be described. FIG. 2A shows the state of an SiRN film actually formed on a tunnel oxide film by using the method for forming an SiRN film described above in the vertical film formation apparatus shown in FIG. 1 and is an enlarged view of portion 7 surrounded by the dotted line in FIG. 1.

As shown in FIG. 2A, a plurality of semiconductor substrates 4 are arranged in the vertical direction in the vertical film formation apparatus. Accordingly, the front and rear surfaces of each semiconductor substrate 4 face the rear and front surfaces of semiconductor substrates 4 disposed above and below the semiconductor substrate described above. In case of forming an SiRN film on each tunnel oxide film 11, tunnel oxide films 11 on semiconductor substrates 4 therefore face each other. An SiRN film formed in this state by using the stepping film formation described above has a film thickness distribution that varies as follows: The film is thicker at the center of each semiconductor substrate 4, whereas being thinner in the vicinity of each end of semiconductor substrate 4, as shown in FIG. 2B. In the formation of an SiRN film, in which DCS and ammonia are used, the ammonia is simply a nitriding agent and hence does not cause the film thickness distribution to vary. It is therefore believed that the spatial distribution of the DCS somehow contributes to the variation in the film thickness distribution of the SiRN film. The present inventor has conducted a variety of experiments from the viewpoint described above and acquired the following findings:

(1) When substrates 4 on each of which an SiN film had been formed instead of tunnel oxide film 11, that is, silicon oxide film 11 were used, the variation in the film thickness distribution decreased.

(2) When semiconductor substrate 10 on which no silicon oxide film 11 had been formed, that is, a silicon single crystal, was used, or when a substrate on which a polycrystalline silicon film had been formed instead of tunnel oxide film 11 was used, the variation in the film thickness distribution also decreased.

(3) Even when a substrate on which silicon oxide film 11 had been formed was used, but when monosilane (SiH₄) or disilane (Si₂H₆) was used instead of DCS, the variation in the film thickness distribution decreased. Using monosilane or disilane, however, is not practical because variation in the film thickness distribution among semiconductor substrates increases.

(4) When substrate 4 on which silicon oxide film 11 had been formed was combined with DCS, the probability of adsorption of Si onto the silicon oxide film is lower than the probability of adsorption of Si onto SiN or Si. The adsorption speed is therefore slow.

(5) The adsorption speed of Si onto a silicon oxide film depends on the amount of supplied DCS. The greater the amount of supplied DCS, that is, the higher the DCS concentration in a gas phase, the higher the adsorption speed.

(6) The adsorption of Si from DCS continues after the entire surface of a substrate is covered with Si, and the adsorbed Si thickens with the increasing the supply time. This phenomenon differs from a phenomenon in which the adsorption of Si automatically stops after the surfaces of a substrate are covered with Si, in the stepping film formation method typically called ALD (atomic layer deposition).

The results described above show that the variation in the film thickness distribution in the formation of an SiRN film is a specific phenomenon caused by the combination of the formation of tunnel oxide film 11, that is, a silicon oxide film, on the surfaces of a substrate and use of DCS as a raw material gas.

Therefore, when semiconductor substrates 4, the front and rear surfaces of which includes tunnel oxide film 11 formed thereon, are arranged in the vertical direction, and DCS is supplied into the space between semiconductor substrates 4 as shown in FIG. 2A. In this case, the consumption of DCS is insufficient because the speed at which Si is adsorbed onto tunnel oxide film 11 is slow, and hence excess DCS is present in the spaces described above. As a result, the DCS concentration is spatially distributed as follows: The partial pressure of DCS is low in the spaces described above in the vicinity of each end of a semiconductor substrate, where the gases are exhausted relatively efficiently. In contrast, the partial pressure of DCS is high in the vicinity of a central portion of the semiconductor substrate, where the gas exhaust efficiency is low. As described in (5), since the Si adsorption speed depends on the concentration of Si in the gas phase, once the absorption starts, the higher the gas phase concentration, the higher the adsorption speed. The adsorption continuously occurs at the central portion where the DCS partial pressure is high, and hence the Si film is thick. As a result, it is inferred that the film thickness distribution of the SiRN film varies in such a way that the central portion of semiconductor substrate 4 is thick and each end thereof is thin, as shown in FIG. 2B.

Even when a substrate on which a silicon oxide film has been formed is used, but when a stoichiometric SiN film (Si₃N₄) is formed on silicon oxide film as described in (1), the film thickness distribution hardly varies. Although it is expected that the film thickness distribution of the SiN film varies because the SiN film is also formed by using DCS and ammonia as a raw material gas, no variation occurs in practice. Further, even a film formed is an SIRN film which is slightly silicon-rich, the film thickness distribution of the SiRN film also is inhibited, as will be described later. Since there is no means to measure the state of a film formed on the surfaces of a substrate in a film formation chamber heated at 500° C. or higher on the atomic order, the reason for the above situation is not clear. However, when an SiN film is formed, it is necessary to reduce the amount of supplied DCS to about one-fifth of the amount of supplied ammonia. It is expected in this case that no excess DCS is present in the space between the substrates because the amount of supplied DCS decreases and hence the supplied amount of DCS agrees with the speed at which Si is adsorbed onto the surface of a silicon oxide film.

### SUMMARY

In one embodiment, there is provided a nonvolatile storage device comprising:
a tunnel insulating film disposed on a surface of a semiconductor substrate; and
a charge trap layer disposed in contact with an upper surface of the tunnel insulating film, the charge trap layer including a second charge trap film disposed in contact with the upper surface of the tunnel insulating film and a first charge trap film disposed in contact with an upper surface of the second charge trap film.

### BRIEF DESCRIPTION OF THE DRAWINGS

The above features and advantages of the present invention will be more apparent from the following description of certain preferred embodiments taken in conjunction with the accompanying drawings, in which:

FIG. 1 shows a vertical film formation apparatus;

FIGS. 2A and 2B show formation of a silicon nitride film in a stepping film formation process of related art;

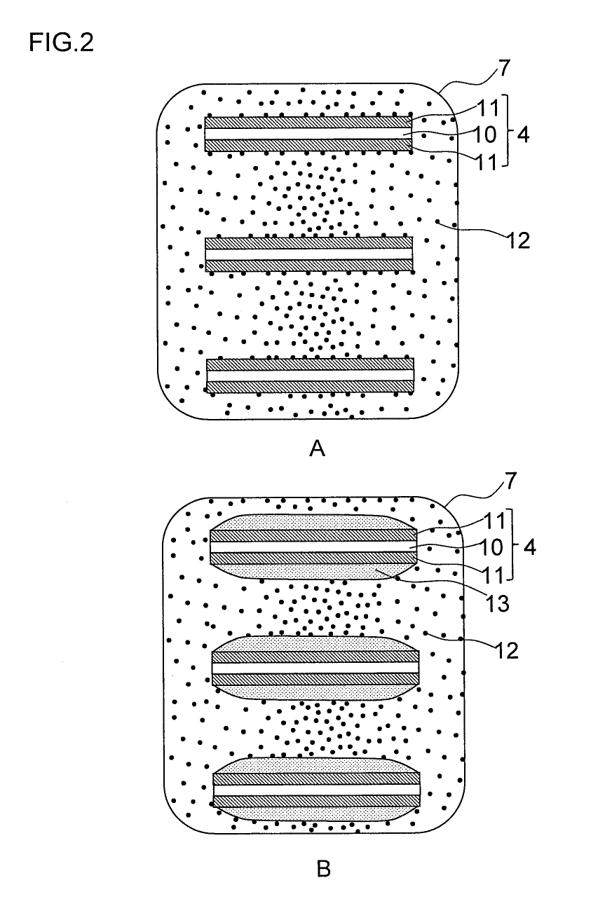

FIGS. 3A and 3B show examples of formation of an SiRN film;

FIG. 4 shows the relationship between the Si/N ratio and the absorption coefficient (k value) of a silicon nitride film;

FIGS. 5A and 5B show an example of formation of an SiRN film;

FIGS. 6A and 6B show another example of formation of an SiRN film;

FIGS. 7A and 7B show another example of formation of an SiRN film;

FIGS. 8A and 8B show an example of a method for manufacturing a semiconductor device according to the present invention;

FIGS. 9A and 9B show another example of the method for manufacturing a semiconductor device according to the present invention;

FIG. 10 is a flowchart showing processes of forming a silicon nitride film;

FIGS. 11A and 11B are time sequences showing the processes of forming a silicon nitride film;

FIG. 12 shows an in-plane film thickness distribution of a first silicon nitride film formed in Experiment Example 1;

FIG. 13 shows the in-plane film thickness distribution of the first silicon nitride film formed in Experiment Example 2;

FIG. 14 shows the in-plane film thickness distribution of the first silicon nitride film formed in Experiment Example 3;

FIG. 15 shows the in-plane film thickness distribution of the first silicon nitride film formed in Experiment Example 4; and

FIG. 16 shows the in-plane film thickness distribution of the silicon nitride film formed in Experiment Example 5.

In the drawings, numerals have the following meanings: 2: film formation chamber, 3: port, 4: semiconductor substrate, 5, 6: nozzle, 10: semiconductor layer, 10a: active region, 11: silicon oxide film, 12: raw material gas, 13: silicon nitride film, 14a: second silicon nitride film (buffer film), 14b: first silicon nitride film, 15a, 15c: first semiconductor substrate, 15b: second semiconductor substrate, 20: isolation region, 23a: tunnel oxide film, 23b: control gate insulating film, 25: control gate electrode, 26: sidewall insulating film, 27: impurity diffusion layer, 28a: first metal silicide, 28b; second metal silicide, 29: interlayer insulating film, 30: contact plug, and 31: bit line.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### (Semiconductor Device)

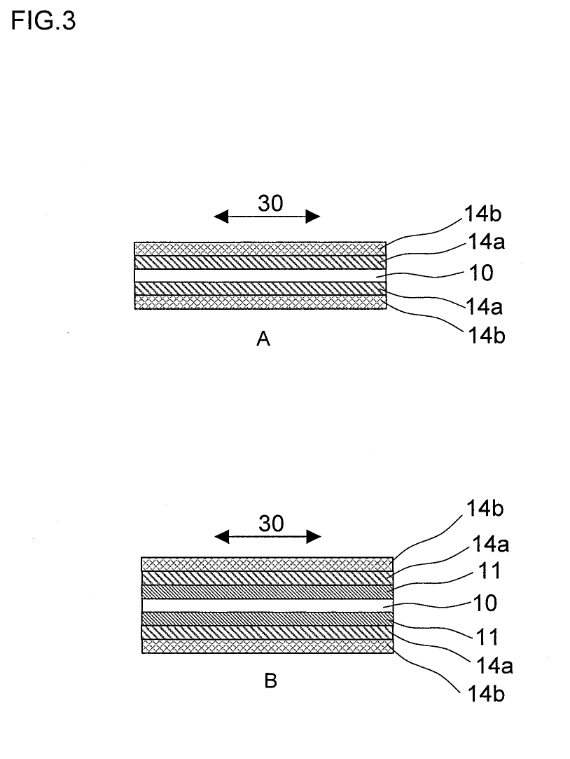

FIGS. 3A and 3B are cross-sectional views showing examples of a silicon nitride film formed in a stepping film formation process using a vertical film formation apparatus. FIG. 3A shows a semiconductor device including second charge trap films 14a each formed of a second silicon nitride film on semiconductor substrate 10 and first charge trap films 14b each formed of a first silicon nitride film on second charge trap films 14a. FIG. 3B shows a semiconductor device including silicon oxide films 11 on semiconductor substrate 10, and second charge trap films 14a each formed of a second silicon nitride film and first charge trap films 14b each formed of a first silicon nitride film on silicon oxide films 11.

In each of the semiconductor devices shown in FIGS. 3A and 3B, each first charge trap film 14b formed of the first silicon nitride film has excellent film thickness uniformity in in-plane direction 30, that is, from one end to the other end along the diameter direction of the semiconductor substrate having a diameter of 300 mm. Accordingly, variation in the film thickness in the in-plane direction is small. The variation in the thickness of first charge trap film 14b in the in-plane direction can, for example, be smaller than or equal to 1.6 nm.

In each of the semiconductor devices shown in FIGS. 3A and 3B, each second charge trap film 14a has optical absorption coefficient k ranging from 0 to 0.20, and each first charge trap film 14b has optical absorption coefficient k ranging from 0.60 to 1.26. A film having optical absorption coefficient k of 0 is an SiN film having a composition of Si₃N₄, and a film having optical absorption coefficient k greater than 0 is a silicon-rich nitride (SiRN) film containing more silicon atoms than Si₃N₄, as will be described later.

Even when silicon oxide films 11 are present on semiconductor substrate 10 as shown in FIG. 3B, second charge trap films 14a each formed of the second silicon nitride film having optical absorption coefficient k ranging from 0 to 0.20 are placed on the surfaces of silicon oxide films 11. As a result, it is possible to suppress variation in the film thickness distribution of SiRN films (first silicon nitride films) 14b having optical absorption coefficient k ranging from 0.60 to 1.26 and provided on second charge trap films 14a. Furthermore, a semiconductor device having an excellent charge trap characteristic and reduced characteristic variation can be provided.

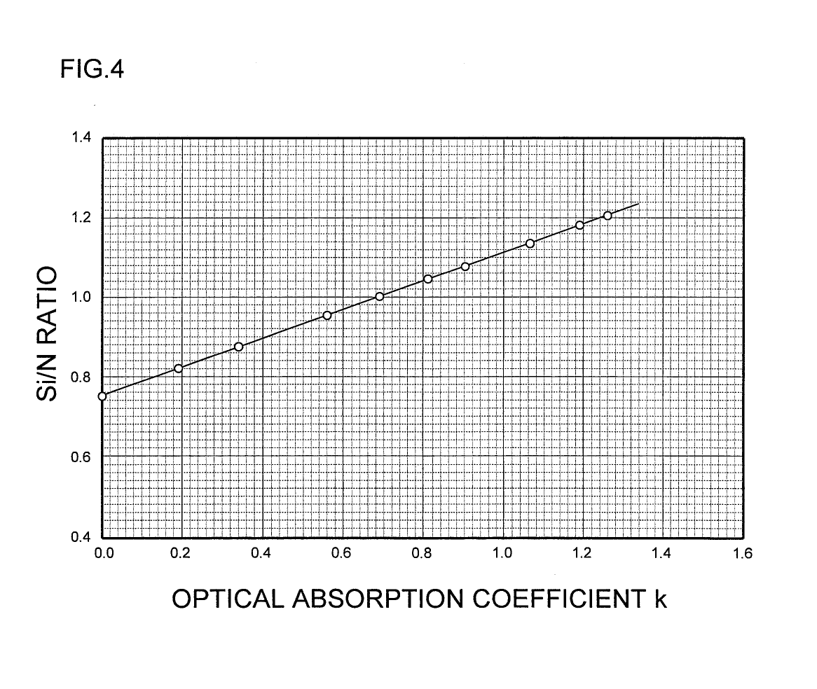

Optical absorption coefficient k of each of the silicon nitride films was measured by using known spectroscopic ellipsometry. FIG. 4 shows the relationship between optical absorption coefficient k of one of the silicon nitride films and the Si/N ratio thereof. The Si/N ratio was determined by using a procedure based on X-ray photoelectron spectroscopy (XPS). In this procedure, a single cycles in which a film was step-etched in the depth direction thereof and the Si/N ratio was determined using XPS analysis, were repeated. The Si/N ratios obtained from each XPS analysis are averaged in the depth direction, to determine the Si/N ratio of the silicon nitride film finally. As shown in FIG. 4, the optical absorption coefficient (k value) and the Si/N ratio are proportional to each other, and the Si/N ratio can be calculated when the absorption coefficient (k value) is derived from the spectroscopic ellipsometry. The k value of second silicon nitride film 14a ranging from 0 to 0.20 corresponds to the Si/N ratio ranging from 0.75 to 0.83. The k value of SiRN film (first silicon nitride film) 14b ranging from 0.60 to 1.26 corresponds to the Si/N ratio ranging from 0.97 to 1.21.

FIGS. 3A and 3B show the case where the first and second silicon nitride films are formed on both sides of the semiconductor substrate, but only the first and second silicon nitride films, elements, and other components formed on one side of the semiconductor substrate may actually function as a semiconductor device.

The k value of SiRN film (first silicon nitride film) 14b preferably ranges from 0.8 to 1.22 (Si/N ratio: from 1.04 to 1.19), more preferably from 1.10 to 1.20 (Si/N ratio: from 1.15 to 1.19). When the k value of SiRN film (first silicon nitride film) 14b is smaller than 0.6, it is difficult to improve the charge trapping characteristic of a memory or any other semiconductor device to which the present invention is applied. On the other hand, when the k value is greater than 1.26, the advantageous effect of the intentionally provided second silicon nitride film is degraded, resulting in an increase in variation in the characteristics of the semiconductor device.

The k value of second silicon nitride film 14a preferably ranges from 0 to 0.2. When the k value is greater than 0.2, the film thickness distribution tends to vary when second silicon nitride film 14a itself is formed. The thickness of second silicon nitride film 14a ranges from 0.1 to 2 nm, preferably from 0.5 to 1.5 nm, more preferably from 0.8 to 1.2 nm.

### (Nonvolatile Storage Device)

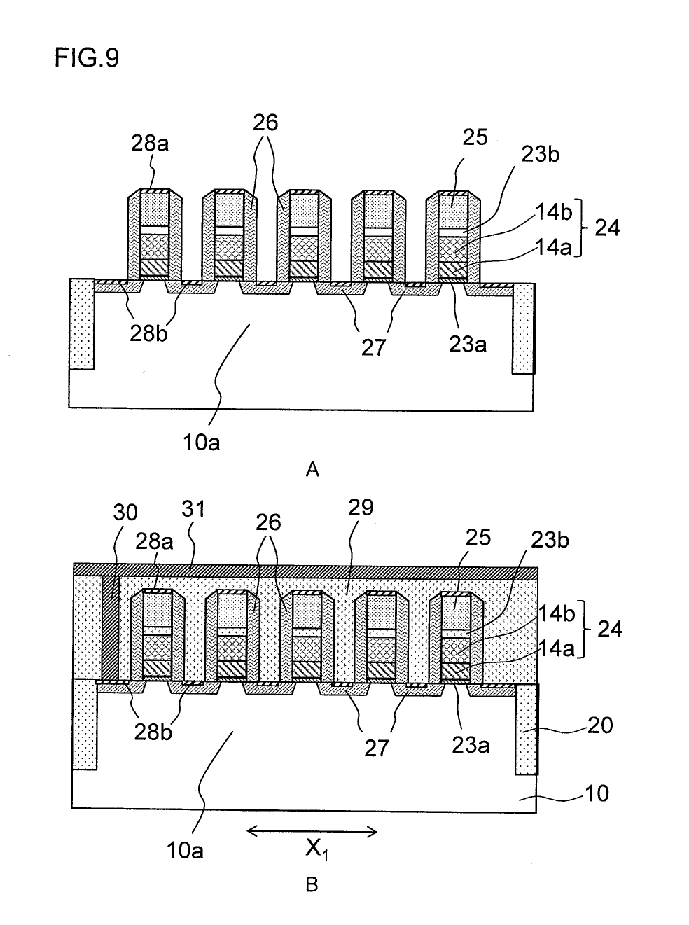

FIG. 9B is a cross-sectional view diagrammatically showing an example of a memory cell of a NAND flash memory device (nonvolatile storage device) using an SiRN film. For example, the memory cell includes isolation region 20 formed of an insulating film and formed in semiconductor substrate 10 made of p-type single crystalline silicon and active region 10a surrounded by isolation region 20 and extending in one direction (first direction X₁). Although FIG. 9B shows only one active region 10a, a plurality of active regions 10a are provided in a single memory device.

A plurality of charge trap cells are continuously arranged on the surface of active region 10a in first direction X₁ with impurity diffusion layers 27 interposed between the charge trap cells. Since semiconductor substrate 10 is of p type, impurity diffusion layers 27 are made of an n-type material. That is, impurity diffusion layers 27 are formed by introducing phosphorus, arsenide, or any other suitable n-type impurity into the surface of semiconductor substrate 10. The concentration of the impurity ranges from 1×20²⁰ to 1×20²¹ (atoms/cm³). Each of the cells includes tunnel insulating film 23a disposed on the surface of semiconductor substrate 10 and charge trap layer 24 disposed in contact with the upper surface of tunnel insulating film 23a, and charge trap layer 24 is formed of second charge trap film 14a disposed in contact with the upper surface of tunnel insulating film 23a and first charge trap film 14b disposed in contact with the upper surface of second charge trap film 14a.

More specifically, each cell includes tunnel oxide film 23a formed of a silicon oxide film disposed on the surface of semiconductor substrate 10, second charge trap film 14a disposed in contact with the upper surface of tunnel oxide film 23a, first charge trap film 14b disposed in contact with the upper surface of second charge trap film 14a, control gate insulating film 23b formed of a silicon oxide film or a silicon oxynitride film disposed in contact with the upper surface of first charge trap film 14b, and control gate electrode 25 made of a conductor, such as a silicon film, disposed in contact with the upper surface of control gate insulating film 23b.

Second charge trap film 14a is formed of the second silicon nitride film, and first charge trap film 14b is formed of the first silicon nitride film. Further, first charge trap film 14b is formed of a silicon nitride film having optical absorption coefficient k greater than that of second charge trap film 14a. Specifically, optical absorption coefficient k of second charge trap film 14a ranges from 0 to 0.20, and optical absorption coefficient k of first charge trap film 14b ranges from 0.6 to 1.26.

The thickness of tunnel oxide film 23a ranges from 0.5 to 2.0 nm. The thickness of second charge trap film 14a ranges from 0.1 to 2.0 nm. The thickness of first charge trap film 14b ranges from 12 to 15 nm. The thickness of control gate insulating film 23b ranges from 3 to 7 nm. Control gate insulating film 23b is formed of a silicon oxide film produced by thermally oxidizing the upper surface of first silicon nitride film 14b. Control gate insulating film 23b may alternatively be formed of a silicon oxide film deposited on the upper surface of first silicon nitride film 14b using a CVD process. Control gate insulating film 23b has a function of preventing charge trapped in charge trap layer 24 from leaking to the control gate electrode. Control gate electrode 25 can be formed of a stacked film including a polycrystalline silicon film containing an impurity and first metal silicide film 28a made, for example, of a nickel silicide or a cobalt silicide, and disposed on the polycrystalline silicon film. Control gate electrode 25 may alternatively be formed of a stacked film produced by further placing a metal film on first metal silicide film 28a. Control gate electrode 25 forms a word line that is parallel to the surface of semiconductor substrate 10 and extends in a second direction perpendicular to first direction X₁, along which active region 10a extends. Control gate electrode 25, which forms a word line, extends over a plurality of active regions 10a aligned in the second direction.

Since charge trap layer 24 is formed of second silicon nitride film 14a and first silicon nitride film 14b, and a single cell is formed of silicon film 25 (S), silicon oxide film 23b (O), silicon nitride film 24 (N), silicon oxide film 23a (O), and silicon substrate 10 (S) in this order from above, the cell has an SONOS structure.

Sidewall insulating film 26 formed of a silicon oxide film is provided on each sidewall of the SONO structure, which does not include silicon substrate 10 but includes first metal silicide film 28a, and interlayer insulating film 29 formed of a silicon oxide film is provided so that it covers all the cells. Bit line 31 extending in the first direction, along which active region 10a extends, is provided on interlayer insulating film 29. Bit line 31 includes a monolayer film made of tungsten or any other suitable metal or a stacked layer film made of a metal film and a metal compound, such as a titanium nitride. Bit line 31 is electrically connected to impurity diffusion layer 27 positioned at an end of active region 10a via bit-line contact plug 30 provided through interlayer insulating film 29. To reduce contact resistance, second metal silicide 28b made, for example, of a nickel silicide, is disposed between bit-line contact plug 30 and impurity diffusion layer 27. Bit-line contact plug 30 is formed of a stacked film of a barrier film made, for example, of a titanium nitride and a metal film made, for example, of tungsten. Second metal silicide 28b is also disposed on parts of the upper surfaces of the other impurity diffusion layers 27. FIG. 9B shows a NAND flash memory, but the present invention is not limited thereto and is applicable to a NOR flash memory.

The nonvolatile storage device shown in FIG. 9B has a configuration in which the first charge trap film is disposed via the second charge trap film. The first charge trap film is formed of first silicon nitride film 14b, which excels in charge trapping characteristic and has optical absorption coefficient k ranging from 0.6 to 1.26. The second charge trap film is formed of second silicon nitride film 14a, which is disposed in contact with the upper surface of tunnel oxide film 23a and has optical absorption coefficient k ranging from 0 to 0.20. The second charge trap film described above has a function of improving the film thickness uniformity of the first charge trap film. Accordingly, it is possible to prevent the thickness of first silicon nitride film 14b, which forms an SiRN film from varying, unlike a case where second silicon nitride film 14a is not present. As a result, it is possible to provide the resultant nonvolatile storage device that has a small amount of variation in characteristics among the cells and an excellent charge trapping characteristic.

### (Method for Manufacturing Semiconductor Device)

An SiRN film forming method applied to a semiconductor device manufacturing method uses the stepping film formation process described above. That is, after a plurality of semiconductor substrates which includes a tunnel oxide film or no tunnel oxide film formed thereon are placed in a film formation chamber of a vertical film formation apparatus, a single cycle formed of the following first to fourth steps is repeated multiple times with a predetermined temperature, for example, 630° C., maintained until a film is formed to a desired film thickness:

(a1) supplying DCS (first raw material gas), which works as an Si raw material, and adsorbing deposited Si onto each of the semiconductor substrates (first step),
(a2) exhausting DCS (first raw material gas) that has not reacted out of the film formation chamber (second step),
(a3) supplying ammonia (second raw material gas), which works as a nitriding raw material, and nitriding the adsorbed Si to convert Si into SiRN (third step), and
(a4) exhausting ammonia (second raw material gas) that has not reacted out of the film formation chamber (fourth step).

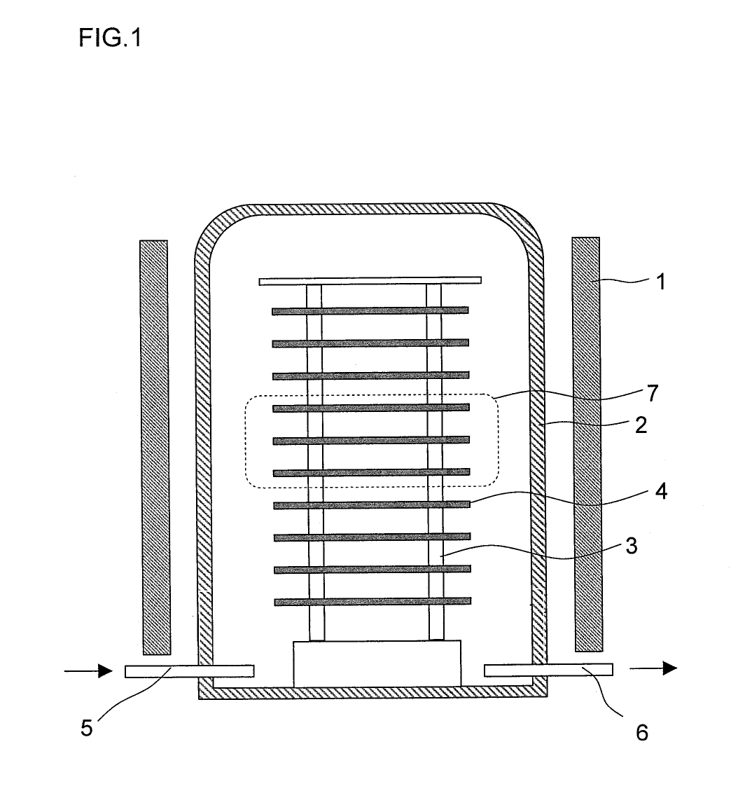

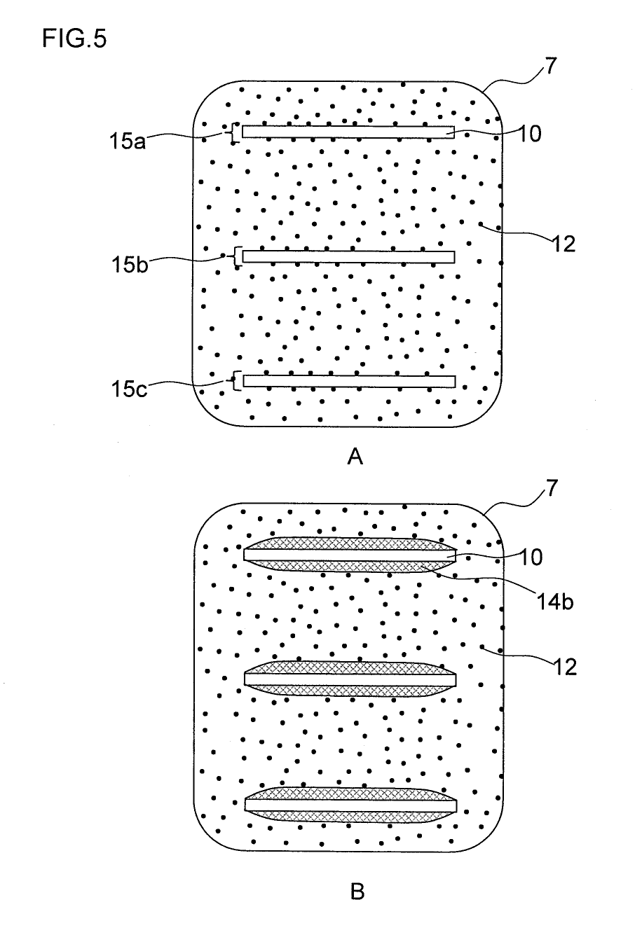

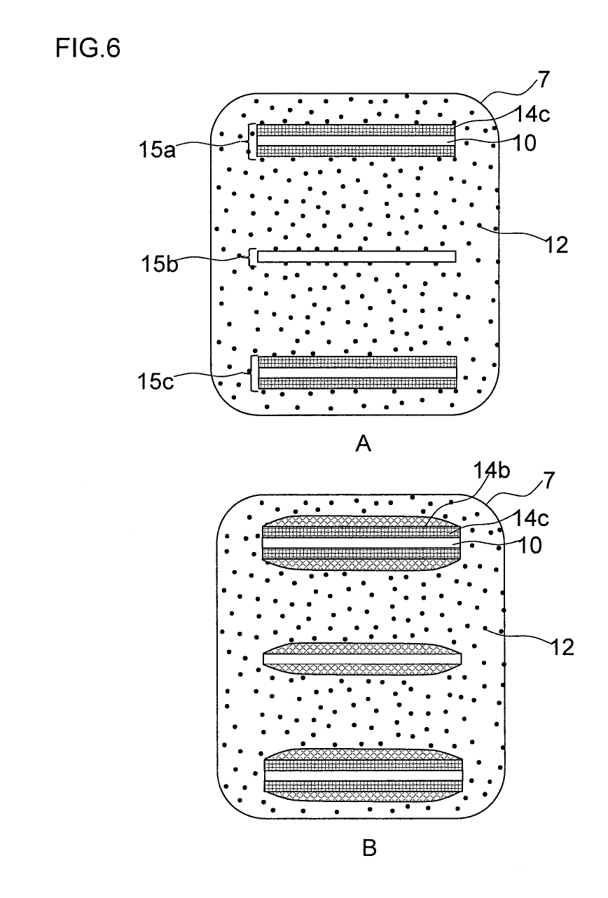

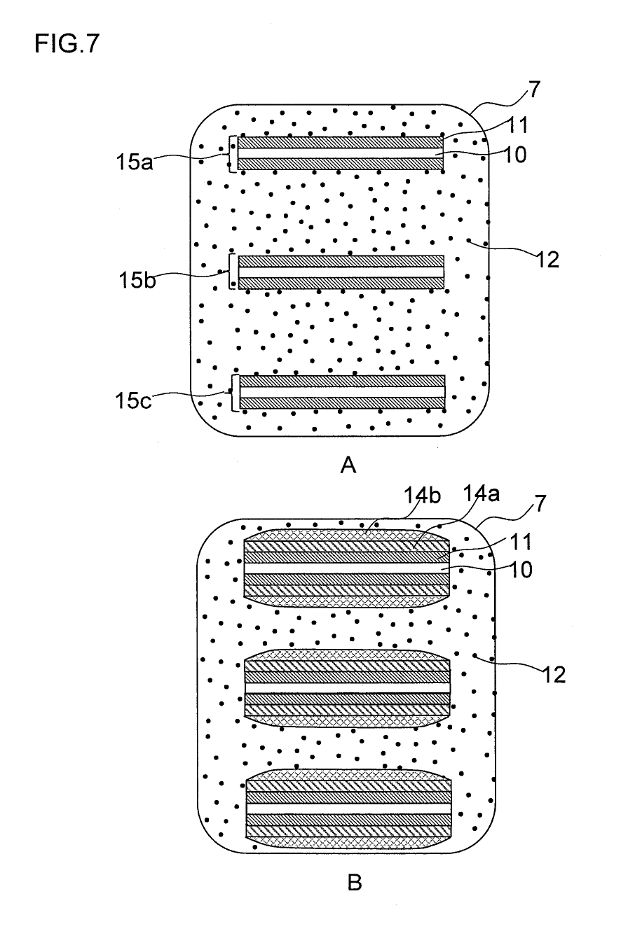

Firstly, in a case where first semiconductor substrates are disposed above and below a second semiconductor substrate on which a semiconductor device is to be formed and an Si RN film is formed in the stepping film formation process described above, a description will be made of an effect of the state of the surfaces of the first semiconductor substrates on the film thickness distribution of the SiRN film formed on the second semiconductor substrate with reference to FIGS. 5A and 5B, 6A and 6B, and 7A and 7B. FIGS. 5A and 5B, 6A and 6B, and 7A and 7B each show an example of methods for manufacturing semiconductor devices and are enlarged views of portions 7 surrounded by the dotted line in the vertical film formation apparatus in shown FIG. 1. FIGS. 6A and 6B and 7A and 7B show methods for manufacturing the semiconductor devices shown in FIGS. 3A and 3B, respectively.

First, second semiconductor substrate 15b and first semiconductor substrates 15a and 15c which are disposed above and below second semiconductor substrate 15b, are placed in film formation chamber 2 of a vertical film formation apparatus, as shown in FIG. 5A. The surfaces of second semiconductor substrate 15b are made of exposed silicon. The surfaces of first semiconductor substrates 15a and 15c are also made of exposed silicon. FIG. 5A shows only three substrates, but it is preferable that a plurality of second semiconductor substrates are placed in film formation chamber 2 and a plurality of pairs of first semiconductor substrates are disposed above and below each of the plurality of second semiconductor substrates in order to reduce the manufacturing cost. In this case, the first and second semiconductor substrates are alternately disposed in the vertical direction in film formation chamber 2, for example, in the order of a first semiconductor substrate, a second semiconductor substrate, a first semiconductor substrate, a second semiconductor substrate, a first semiconductor substrate, . . . .

SiRN film (first silicon nitride film) 14b is then formed on semiconductor substrate 15b using the stepping film formation process described above, as shown in FIG. 5B. At the time of formation of first silicon nitride film 14b, each of the rear surface of first semiconductor substrate 15a and the front surface of first semiconductor substrate 15c is not formed of a silicon oxide film but is formed of semiconductor layer 10 that is silicon. Raw material gas 12 formed of DCS therefore tends to adsorb to the rear surface of first semiconductor substrate 15a and the front surface of first semiconductor substrate 15c. Accordingly, the amount of raw material gas 12 that has not reacted and is present between second semiconductor substrate 15b and first semiconductor substrates 15a, 15c decreases. As a result, the difference in in-plane partial pressure (molar quantity) of raw material gas 12 present between second semiconductor substrate 15b and first semiconductor substrates 15a, 15c decreases, whereby first silicon nitride film 14b is formed more uniformly in the in-plane direction of second semiconductor substrate 15b. The variation in the film thickness distribution of first silicon nitride film 14b formed on second semiconductor substrate 15b is therefore smaller than the variation in the film thickness distribution in a case where a silicon oxide is formed on the rear surface of first semiconductor substrate 15a and the front surface of first semiconductor substrate 15c. Since first semiconductor substrates 15a and 15c used in FIGS. 5A and 5B are made of silicon, an unintentional natural oxide film is formed on each of the surfaces thereof. However, the proportion of the natural oxide film that covers the substrate surfaces is smaller than the proportion of an intentionally formed silicon oxide film that covers the substrate surfaces. The natural oxide film does not cover the entire substrate surfaces. The DCS adsorption probability is therefore greater than that in a case where a silicon oxide film is intentionally formed on the rear surface of first semiconductor substrate 15a and the front surface of first semiconductor substrate 15c. Accordingly, the difference in the partial pressure (molar quantity) of raw material gas 12 in the in-plane direction decreases. As a result, the variation in the film thickness distribution of the first silicon nitride film can be reduced as compared with a case where a silicon oxide film is intentionally formed. The “silicon oxide film” as a film that covers substrate surfaces means an intentionally formed silicon oxide film, and a silicon oxide film formed on semiconductor substrate surfaces in the form of unintentional natural oxide film described above does not correspond to the “silicon oxide film” described in the present example.

FIG. 6A shows another example in which second semiconductor substrate 15b whose surfaces are made of exposed silicon and first semiconductor substrates 15a and 15c are placed in film formation chamber 2 of the vertical film formation apparatus. Each of the first semiconductor substrates 15a and 15c includes SiN film (silicon nitride film: Si₃N₄) 14c formed in advance as a film that covers the substrate surfaces. The silicon nitride film is formed by using an LPCVD (low-pressure chemical vapor deposition, low-pressure CVD) process in which DCS and ammonia are supplied simultaneously and allowed to react with each other in a gas phase. SiRN film (first silicon nitride film) 14b is then formed in this state, as shown in FIG. 6B. As described above, the probability at which DCS adsorbs to the surface of an SiN film is higher than the probability at which DCS adsorbs to the surface of a silicon oxide film. DCS is therefore consumed at the rear surface of first semiconductor substrate 15a and the front surface of first semiconductor substrate 15c. As a result, the difference in in-plane partial pressure (molar quantity) of raw material gas 12 present between second semiconductor substrate 15b and first semiconductor substrates 15a, 15c decreases. Accordingly, first silicon nitride film 14b is formed more uniformly in the in-plane direction of second semiconductor substrate 15b.

Since first semiconductor substrates 15a and 15c used in FIGS. 5A and 5B are made of silicon, an unintentional natural oxide film is formed on each of the surfaces thereof and contributes to prevention of DCS adsorption. When an SiN film is formed, however, no natural oxide film is present on the substrate surfaces. The thickness of SiRN film (first silicon nitride film) 14b formed on second semiconductor substrate 15b in the present example becomes therefore more uniform and the variation in the film thickness thereof becomes smaller than in the case shown in FIGS. 5A and 5B.

As clearly shown in FIGS. 5A and 5B and FIGS. 6A and 6B and Comparative Example described later as the method for forming an SiRN film, first semiconductor substrates 15a and 15c are disposed so that they sandwich second semiconductor substrate 15b, on which a semiconductor device is to be formed, from above and below, and each of the surfaces of first semiconductor substrates 15a and 15c is coated with a film other than a silicon oxide film. The configuration described above encourages the adsorption of DCS and reduces the difference in partial pressure of DCS in the space between the substrates. Accordingly, the variation in the film thickness distribution of the SiRN film formed on second semiconductor substrate 15b can be reduced. As the film other than a silicon oxide film, a silicon film (including silicon substrate) or an SiN film having optical absorption coefficient k of 0 (Si/N ratio corresponds to 0.75) can be used. After the first film formation process is finished, each of the surfaces of semiconductor substrate 15b is covered with an SiRN film having optical absorption coefficient k ranging from 0.6 to 1.26. As a result, in a second and the following film formation processes, the state in FIGS. 6A and 6B, in which each surface of first semiconductor substrates 15a and 15c covered with the SiN film are placed, is maintained. Accordingly, the variation in the film thickness distribution of the SiRN film decreases.

FIG. 7A shows another example, and in this example, semiconductor substrates on which silicon oxide films 11 have been formed in advance is used as second semiconductor substrate 15b and first semiconductor substrates 15a and 15c. It is assumed in this example that silicon oxide film 11 is a tunnel oxide film in a flash memory device. After the substrates described above were placed in film formation chamber 2 of the vertical film formation apparatus, second silicon nitride film 14a formed of an SiN film having optical absorption coefficient k of 0 was formed to a thickness of 1 nm using the stepping film formation process described above. First silicon nitride film 14b formed of an SiRN film having optical absorption coefficient k of 1.19 was then formed to a thickness of 13 nm successively in the same apparatus. In the example shown in FIGS. 7A and 7B, the SiN films having optical absorption coefficient k of 0 were formed on each of second semiconductor substrate 15b and first semiconductor substrates 15a and 15c before the SiRN films were formed thereon. DCS is therefore consumed not only at the rear surface of first semiconductor substrate 15a and the front surface of first semiconductor substrate 15c but also at the front and rear surfaces of second semiconductor substrate 15b itself. Accordingly, the DCS spatial concentration distribution in the space between the substrates is becomes more uniform. In the present example, since the front and rear surfaces of all the substrates are coated with an SiN film, which contributes as a DCS consuming material, the variation in the film thickness distribution of the SiRN film is significantly improved, as will be described later in Experiment Examples.

In the example shown in FIGS. 7A and 7B, silicon oxide films 11 are formed also on the surfaces of the first semiconductor substrates, and the state of the first semiconductor substrate is the same as the state of the semiconductor substrate on which a tunnel oxide film to be a component of a flash memory is formed. That is, in FIGS. 6A and 6B, the layer configuration differs between first semiconductor substrates 15a, 15c and second semiconductor substrate 15b at the time of formation of the SiRN film, and first semiconductor substrates 15a and 15c are not assumed to use a semiconductor device. In contrast, in FIGS. 7A and 7B, first semiconductor substrates 15a and 15c have the same configuration as that of second semiconductor substrate 15b, which includes a tunnel oxide film formed thereon and is placed in the vertical film formation apparatus. In other words, each of the first semiconductor substrates can be used as a semiconductor device, and all the substrates placed in the film formation chamber of the vertical film formation apparatus can be used as semiconductor devices. As described above, even when a tunnel oxide films are formed on all the placed substrates, the variation in the film thickness distribution of an SiRN film can be reduced by using the method for forming an SiN film having optical absorption coefficient k of 0 on the tunnel oxide films and forming an SiRN film having optical absorption coefficient k ranging from 0.60 to 1.26 on the SiN film. Second silicon nitride film 14a formed on the tunnel oxide film may be an SiRN film having optical absorption coefficient k greater than 0 but smaller than or equal to 0.20. When optical absorption coefficient k falls within this range, the variation in the film thickness distribution can be reduced as compared with a case where an SiRN film having a k value ranging from 0.60 to 1.26 is directly formed on the tunnel oxide film.

According to the example shown in FIGS. 7A and 7B, the variation in the film thickness distribution of the SiRN film formed on each of the first and second semiconductor substrates can be reduced, whereby the productivity can be at least doubled.

Further, as will be described in later Experiment Example, the k value of the SiRN film can be readily controlled by adjusting the conditions in the stepping film formation process, particularly, the pressure at which DCS and ammonia as raw material gases are supplied and the period for which DCS and ammonia are supplied.

Moreover, when the first and second semiconductor substrates have the same layer configuration and the exposed film on each of the front and rear surfaces of the first and second semiconductor substrates is not a silicon oxide film at the time of formation of an SiRN film as shown in FIGS. 7A and 7B, the first and second semiconductor substrates are only distinguished from each other for the sake of convenience and both the first and second semiconductor substrates after an SiRN film is formed thereon can be used as semiconductor devices in some cases. That is, in a case where semiconductor substrate 1, semiconductor substrate 2, semiconductor substrate 3, semiconductor substrate 4, semiconductor substrate 5, . . . that are the same semiconductor substrate, are arranged in the vertical direction in film formation chamber 2, if semiconductor substrates 2 and 4 are the second semiconductor substrates, semiconductor substrates 1, 3, and 5 disposed above and below semiconductor substrates 2 and 4 are the first semiconductor substrates. Conversely, if semiconductor substrates 1, 3, and 5 are the second semiconductor substrates, semiconductor substrates 2, 4 disposed above and below semiconductor substrates 1, 3, and 5 are the first semiconductor substrates. In the above example, which semiconductor substrates are called the first semiconductor substrates depends on which semiconductor substrates are called the second semiconductor substrates. Any of the semiconductor substrates, which have the same configuration, can be the first or second semiconductor substrate depending on which semiconductor substrates are called the second semiconductor substrates, and the first or second semiconductor substrates are determined only for the sake of convenience. Even in this case, when the first and second semiconductor substrates have the same layer configuration and the exposed film on each of the front and rear surfaces of the first and second semiconductor substrates is not a silicon oxide film at the time of formation of the SiRN film, semiconductor devices formed on the first and second semiconductor substrates have the same configuration and the variation in the film thickness distribution can be reduced to the same extent without any problem.

### (Method for Manufacturing Nonvolatile Storage Device)

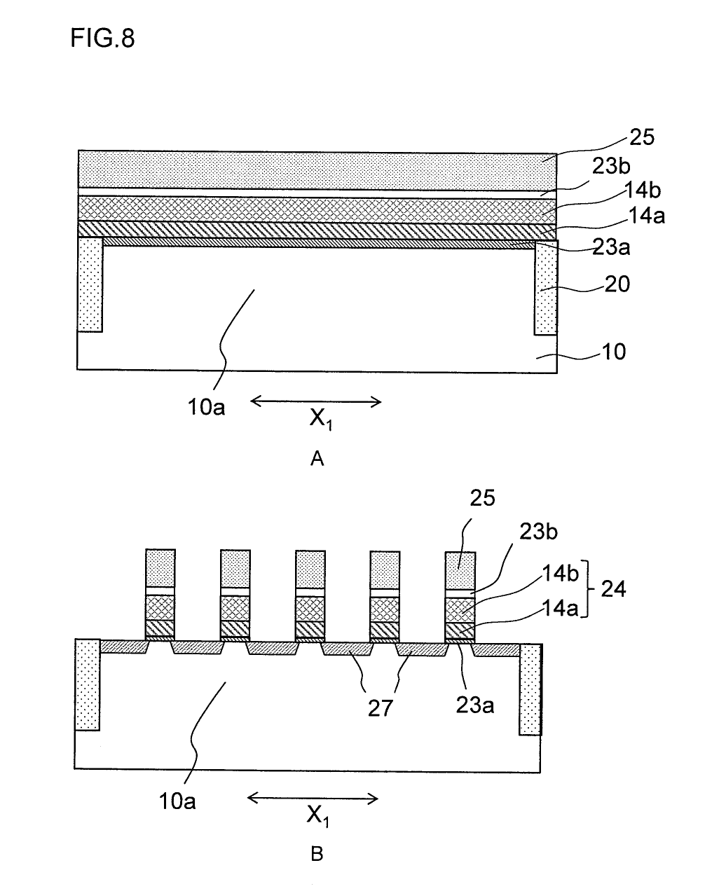

A method for manufacturing a NAND flash memory (nonvolatile storage device) will be described below with reference FIGS. 8A and 8B and FIGS. 9A and 9B.

Isolation region 20 is formed in a superficial portion of semiconductor substrate 10 made of p-type single crystalline silicon, for example, using an STI process, as shown in FIG. 8A. Active region 10a extending in first direction X₁ and surrounded by isolation region 20 is thus formed.

The surface of semiconductor substrate 10 is then thermally oxidized to form a tunnel oxide film 23a made of a silicon oxide film. The thickness of tunnel oxide film 23a, which can range from 0.5 to 2.0 nm, is set at 1.0 nm in this exemplary embodiment.

Semiconductor substrate 10 is then placed in a film formation chamber of a vertical film formation apparatus. After the interior of the film formation chamber is stabilized at 630° C., second silicon nitride film 14a, which forms the second charge trap film, is formed on the upper surface of tunnel oxide film 23a using a stepping film formation process. Second silicon nitride film 14a, which forms second charge trap film 14a, is also called a buffer film. Optical absorption coefficient k of buffer film 14a, which can range from 0 to 0.20, but it is set at 0 in this exemplary embodiment. The thickness of buffer film 14a, which can range from 0.1 to 2.0 nm, preferably ranges from 0.5 to 1.5 nm, more preferably from 0.8 to 1.2 nm. In this exemplary embodiment, it is set at 1 nm.

Subsequently, SiRN film (first silicon nitride film) 14b, which forms a primary charge trap layer, is formed on the upper surface of second silicon nitride film 14a in the same film formation chamber using the stepping film formation process. Optical absorption coefficient k of SiRN film 14b, which forms a primary charge trap layer, can have a k value ranging from 0.6 to 1.26, but it is set at 1.19 in this exemplary embodiment. The thickness of SiRN film 14b, which forms a primary charge trap layer, can range from 12 to 15 nm.

After semiconductor substrate 10 is removed from the film formation chamber, control gate insulating film 23b formed of a silicon oxide film and having a thickness ranging from 3 to 7 nm is formed on the upper surface of SiRN film (first silicon nitride film) 14b. Control gate insulating film 23b is formed by thermally oxidizing the surface of SiRN film 14b or may alternatively be formed using a CVD process. Since the insulation performance of an SiRN film itself is lower than that of a silicon oxide film, it is not preferable to form a control gate electrode directly on the upper surface of SiRN film 14b because charge trapped in SiRN film 14b tends to leak. Control gate insulating film 23b formed of a silicon oxide film therefore functions as a charge leakage prevention film that prevents charge from leaking from the SiRN film, which forms a primary charge trap layer.

A polycrystalline silicon film into which phosphorus is doped, is then formed on the upper surface of control gate insulating film 23b, for example, using a CVD process. The polycrystalline silicon film has a thickness ranging from 20 to 50 nm and forms a control gate electrode. Control gate electrode 25 may alternatively be formed by forming an amorphous silicon film to which phosphorus is doped, shaping the amorphous silicon film into a gate, and heat-treating the shaped amorphous silicon film for polycrystallization. Since an amorphous silicon film has no grain boundary, it can be processed in a more precise manner than a polycrystalline silicon film. Further, a silicon film formed by heat-treating an amorphous silicon film into a polycrystalline silicon film contains crystal grains larger than those of a silicon film formed as polycrystalline silicon at the time of film formation and is hence advantageous in reduction in resistance of the control gate electrode used as a word line.

The control gate electrode is then patterned by using photolithography and dry etching technologies, as shown in FIG. 8B. The control gate electrode, which forms a word line, is patterned so that the resultant pattern extends in the direction perpendicular to first direction X₁ and parallel to the surface of semiconductor substrate 10. Specifically, a mask film (not shown) is formed on the control gate electrode by using a photolithography technology, and polycrystalline silicon film 25, silicon oxide film 23b, SiRN film 14b, buffer film 14a, and tunnel oxide film 23a are sequentially etched by using a dry etching technology to form an SONOS gate structure. “N” of the term SONOS corresponds to charge trap layer 24 formed of SiRN film 14b, which forms a primary charge trap layer, and silicon nitride film 14a, which forms the buffer film. Silicon nitride film 14a having optical absorption coefficient k ranging from 0 to 0.20 also functions as charge trap layer 24 although not as excellently as the SiRN film having optical absorption coefficient k ranging from 0.60 to 1.26.

Phosphorus, arsenide, or any other suitable n-type impurity is then injected into the entire surface of semiconductor substrate 10 using an ion injection process to form impurity diffusion layers 27. As a result, the surface of semiconductor substrate 10 positioned immediately below adjacent SONOS gates is electrically connected via corresponding impurity diffusion layer 27.

After a silicon oxide film is formed over the entire surface, the silicon oxide film is etched back using a dry etching process to form sidewall insulating film 26 formed of a silicon oxide film on the sidewalls of each of the SONOS gates, as shown in FIG. 9A.

A metal is then formed onto the entire surface using the sputtering method, and the resultant structure is heat-treated to simultaneously and selectively form first metal silicide 28a on the upper surface of each control gate electrode 25 and second metal silicide 28b on the exposed upper surface of each impurity diffusion layer 27. The term “selectively” means that the metal silicide is formed only on a portion where the metal comes into contact with silicon. The metal that has been formed on the insulating film and therefore has not reacted, is then removed. A word line formed of control gate electrode 25 is therefore made of first metal silicide film 28a formed on the polycrystalline silicon film. A lower-resistance word line is thus formed. The metal described above can, for example, be nickel, cobalt, or titanium. Second metal silicide 28b formed on the exposed surface of each impurity diffusion layer 27 contributes to reduction in contact resistance.

Interlayer insulating film 29 is then formed using an application process or a CVD process so that it covers all the SONOS gates, as shown in FIG. 9B. A contact hole is then formed in interlayer insulating film 29 above impurity diffusion layer 27 located at an end of active region 10a by using lithography and dry etching technologies, and the contact hole is then filled with a conductor to form contact plug 30. After a metal film is formed over the entire surface, the metal film is etched by using lithography and dry etching technologies to form bit line 31 extending in first direction X₁. Bit line 31 is connected to impurity diffusion layer 27 via contact plug 30. A memory cell of a flash memory is thus formed by carrying out the steps described above.

In the flash memory shown in FIG. 9B, charge trap layer 24 is positively or negatively charged for writing information and charge is discharged from charge trap layer 24 for erasing information. By making use of change of a voltage across control gate electrode 25 that is necessary to turn on the channel (threshold voltage) changes based on the charged state of charge trap layer 24, information is read.

In the exemplary embodiment, charge trap layer 24 is formed of first and second silicon nitride films 14b, 14a. By using an SiRN film having an Si/N ratio greater than that of Si₃N₄ as the first silicon nitride film, the charge trapping characteristic can be improved. Further, the amount of charge trapped in the charge trap layer is greatly affected by the variation in the thickness of the charge trap layer. In the exemplary embodiment, the thickness of first silicon nitride film 14b is uniform in the in-plane direction, it is possible to provide a flash memory device having excellent operation characteristics because the variation in the amount of trapped charge is reduced.

### Experiment Example 1

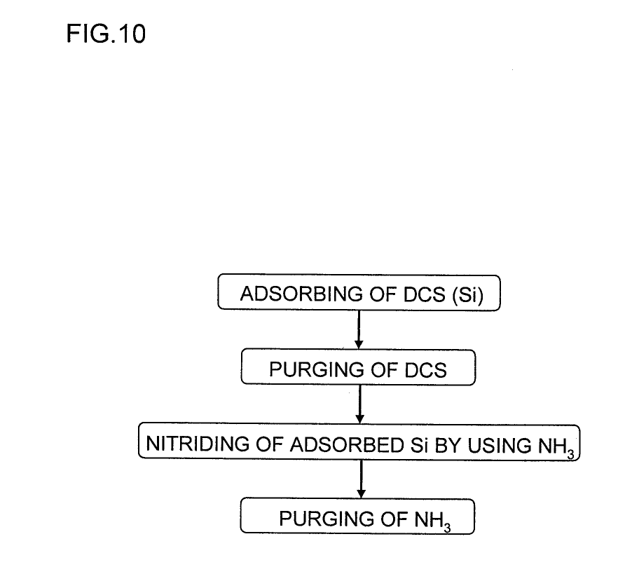

Semiconductor substrates whose surfaces were made of exposed silicon, were placed in the vertical direction in the vertical film formation apparatus shown in FIG. 1, as shown in FIG. 5A. It was assumed among the semiconductor substrates that semiconductor substrates 15a and 15c were the first semiconductor substrates and semiconductor substrate 15b was the second semiconductor substrate, and an SiRN film (first silicon nitride film) having optical absorption coefficient k of 1.19 was formed. The first silicon nitride film was formed by using a stepping film formation process In the stepping film formation process, a single cycle formed of (a1) adsorbing DCS (Si), (a2) purging DCS, (a3) nitriding the adsorbed Si by using NH₃, and (a4) purging NH₃ shown in FIG. 10 was repeated multiple times.

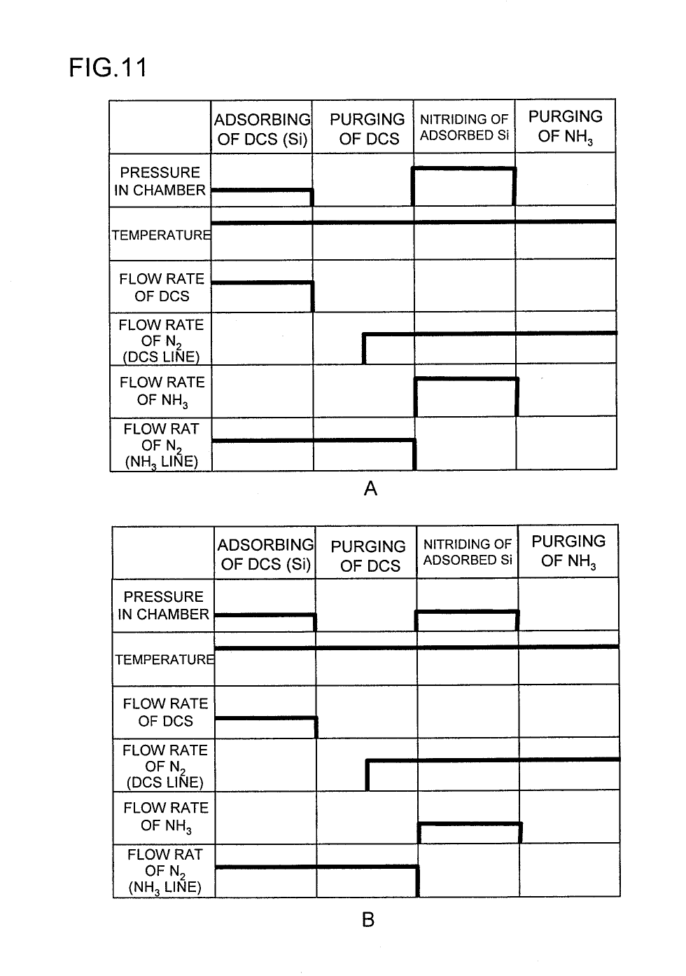

Specifically, the single cycle was carried out in accordance with the time sequence shown in FIG. 11B. In the stepping film formation process shown in FIG. 11B, when DCS or NH₃ was supplied, N₂ was simultaneously supplied. The pressure in the film formation chamber was therefore the partial pressure of DCS plus the partial pressure of N₂ or the partial pressure of NH₃ plus the partial pressure of N₂. In the following description, the pressure in the film formation chamber shown in FIG. 11B means the partial pressure of DCS or NH₃ with respect to the total pressure of the supplied gases including N₂ to simplify the description.

First, after the silicon substrates were placed in the film formation chamber, they were left standing until the temperature was stabilized at 630° C. while N₂ was supplied through an NH₃ line. After the temperature was stabilized, DCS was supplied at a pressure of 12 Pa for 125 seconds. The DCS was then purged for 10 seconds while N₂ was supplied in a high vacuum state. NH₃ was then supplied at a pressure of 48 Pa for 50 seconds. The NH₃ was then purged for 10 seconds while N₂ was supplied in a high vacuum state. A single cycle formed of the steps described above was repeated until the thickness of the SiRN film reached 13 nm. Since each of the gases is supplied under a specific condition thereof in a stepping film formation process, it is difficult to compare the amount of supplied DCS with the amount of supplied NH₃ between different film formation conditions. For convenience sake, the total amount of gas molecules (molar quantity) supplied to a substrate surface is expressed by the product of the pressure and the supply period. In the case described above, the total amount of DCS is 1500 (Pa×sec) and total amount of NH₃ is 2400 (Pa×sec). The total amount of NH₃ is about 1.5 times the total amount of DCS. To form an SiN film (Si₃H₄) having an Si/N ratio of 0.75, the molar quantity of NH₃ typically needs to be at least five times the molar quantity of DCS. In the case described above, the total amount of NH₃ is relatively short of the necessary amount, and a silicon nitride film formed under the condition describe above is an SiRN film having optical absorption coefficient k of 1.19 (corresponding to Si/N ratio of 1.18).

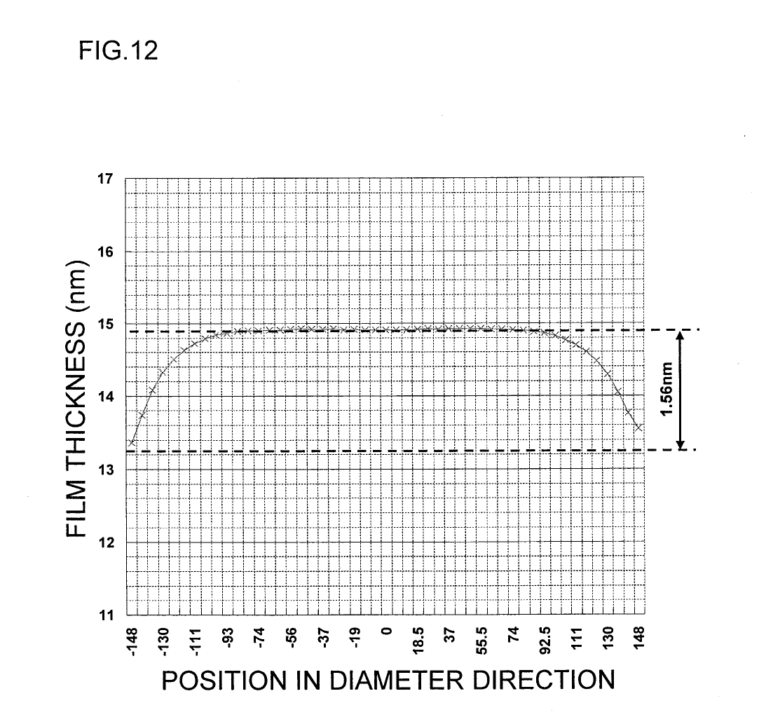

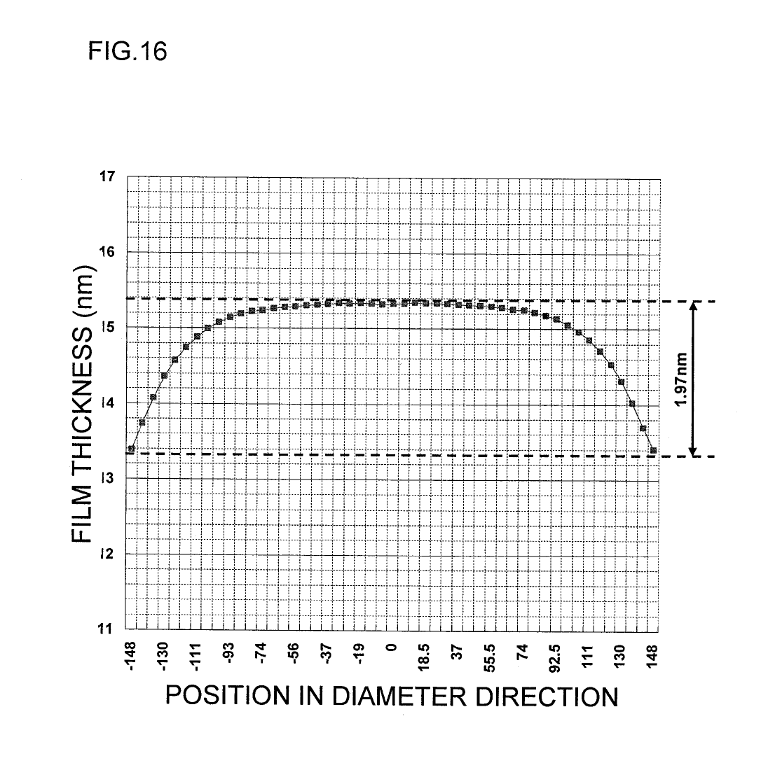

The thickness of the thus formed first silicon nitride film on second semiconductor substrate 15b was measured at 49 points along the diameter of the substrate. FIG. 12 shows measurement results. In FIG. 12, the marking “0” along the X axis represents the center of second semiconductor substrate 15b. The marking “−148” at the left end in the X-axis direction represents one end of second semiconductor substrate 15b along the diameter thereof, and the marking “148” at the right end in the X-axis direction represents the other end of second semiconductor substrate 15b along the diameter thereof (located on the opposite side of the center to the one end). The thickness of the first silicon nitride film is thin in the vicinity of the one and other ends of second semiconductor substrate 15b and substantially constant in the other portions, as shown in FIG. 12. The variation in the film thickness along the diameter of the substrate (difference between maximum thickness and minimum thickness of first silicon nitride film) is 1.56 nm, which is smaller than the variation in Comparative Example 1 (FIG. 16, 1.97 nm), which will be described later.

### Experiment Example 2

An SiRN film (first silicon nitride film) having optical absorption coefficient k of 1.19 was formed using the stepping film formation process under the same conditions as those in Experiment Example 1 except that the following matter: The second semiconductor substrate 15b whose surfaces were made of exposed silicon, and the first semiconductor substrate whose surfaces were covered with an SiN film were alternately arranged in the vertical direction, as shown in FIG. 6A. SiN film (Si₃H₄) 14c that covers the surfaces of each of the first semiconductor substrates shown using FIG. 6A was formed in an LPCVD (low-pressure chemical vapor deposition, low-pressure CVD) process before the substrates were placed in the vertical film formation apparatus by using another apparatus. The conditions of the LPCVD process were as follows: DCS and NH₃ were used as raw material gases; DCS and NH₃ were simultaneously supplied at the flow rate ratio of 1:20; the total pressure was 66 Pa; and the temperature was 760° C.

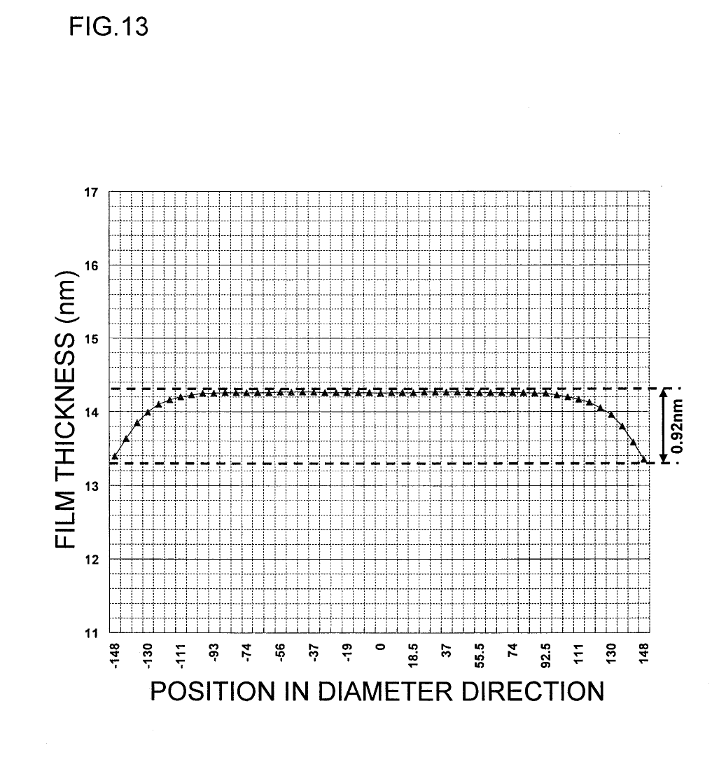

The thickness of the thus formed first silicon nitride film on second semiconductor substrate 15b was measured at 49 points along the diameter of the substrate. FIG. 13 shows measurement results. The variation in the thickness of the first silicon nitride film along the diameter of the substrate is 0.92 nm as shown in FIG. 13, which is further smaller than the variation in Experiment Example 1. The reason for this is as follows: An unintentional natural oxide film was formed and distributed on the substrate surfaces made of exposed silicon. Since the natural oxide film, which is also made of a silicon oxide, it contributes to inhibition of DCS adsorption. Since the proportion of the natural oxide film that covers the surfaces is smaller than the proportion of an intentionally formed silicon oxide film, the variation in the film thickness distribution of the SiRN film is smaller than the variation in film thickness in distribution of a silicon oxide film formed using a thermal oxidation process. On the other hand, in Experiment Example 2, since no natural oxide film is present on the SiN film, the DCS adsorption probability increases, whereby the adsorption and consumption of DCS on the substrates is encouraged, and excess DCS present in the space between the substrates decreases. It is believed that since the degree of nonuniformity of the partial pressure of DCS in the space between the substrates decreases, the film is formed uniformly on second semiconductor substrate 15b. In Experiment Example 2 as well, second semiconductor substrate 15b has surfaces made of exposed silicon, which inhibits adsorption of DCS onto second semiconductor substrate 15b itself. If an ideal silicon substrate on which no natural oxide film is formed, is used, it is expected in Experiment Examples 1 and 2 that the variation in the thickness of the SiRN film further decreases.

### Experiment Example 3

Substrates the surfaces of each of which were covered with silicon oxide film 11 formed using a thermal oxidation process, were placed in the vertical direction in the vertical film formation apparatus shown in FIG. 1, as shown in FIG. 7A. It was assumed that among the substrates, semiconductor substrates 15a and 15c were the first semiconductor substrates and semiconductor substrate 15b was the second semiconductor substrate, and SiRN film (first silicon nitride film) 14b having optical absorption coefficient k of 1.19 was formed using the stepping film formation process. In Experiment Example 3, SiN film (second silicon nitride film) 14a having optical absorption coefficient k of 0 was formed using the stepping film formation process before first silicon nitride film 14b was formed. The thickness of second silicon nitride film 14a was set at 1 nm.

The second silicon nitride film was formed using the stepping film formation process shown in FIG. 10, in which a single cycle formed of (b1) adsorbing DCS (Si), (b2) purging DCS, (b3) nitriding the adsorbed Si by using NH₃, and (b4) purging NH₃, was repeated multiple times. Specifically, the single cycle was carried out in accordance with the time sequence shown in FIG. 11A. In Experiment Example 3 as well, the pressure means the partial pressure of DCS or NH₃, as in Experiment Example 1.

First, after the semiconductor substrates were placed in the film formation chamber, they were left standing until the temperature was stabilized at 630° C. while N₂ was supplied through the NH₃ line. After the temperature was stabilized, DCS was supplied at a pressure of 17 Pa for 6 seconds. The DCS was then purged for 10 seconds while N₂ was supplied in a high vacuum state. NH₃ was then supplied at a pressure of 340 Pa for 24 seconds. The NH₃ was then purged for 10 seconds while N₂ was supplied in a high vacuum state. A single cycle formed of the steps described above was repeated until the thickness of the SiN film reached 1 nm.

The total amount of gas molecules (molar quantity) supplied to the substrate surfaces is expressed by the product of the pressure and the supply period, as in Experiment Example 1. The total amount of DCS is 102 (Pa×sec), and the total amount of NH₃ is 8160 (Pa×sec). The total amount of NH₃ is 80 times the total amount of DCS. To form an SiN film (Si₃H₄) having an Si/N ratio of 0.75, the molar quantity of NH₃ typically needs to be at least five times the molar quantity of DCS. Under the film formation conditions described above, the total amount of NH₃ is sufficiently greater than the necessary amount, and a silicon nitride film formed under the conditions describe above is an SiN film having optical absorption coefficient k of 0 (corresponding to Si/N ratio of 0.75).

SiN film (second silicon nitride film) 14a having optical absorption coefficient k of 0 was formed to a thickness of 1 nm on the upper surface of silicon oxide film 11. After that, SiRN film (first silicon nitride film) 14b having optical absorption coefficient k of 1.19 was formed on the upper surface of SiN film 14a using the stepping film formation process under the same conditions as those in Experiment Example 1.

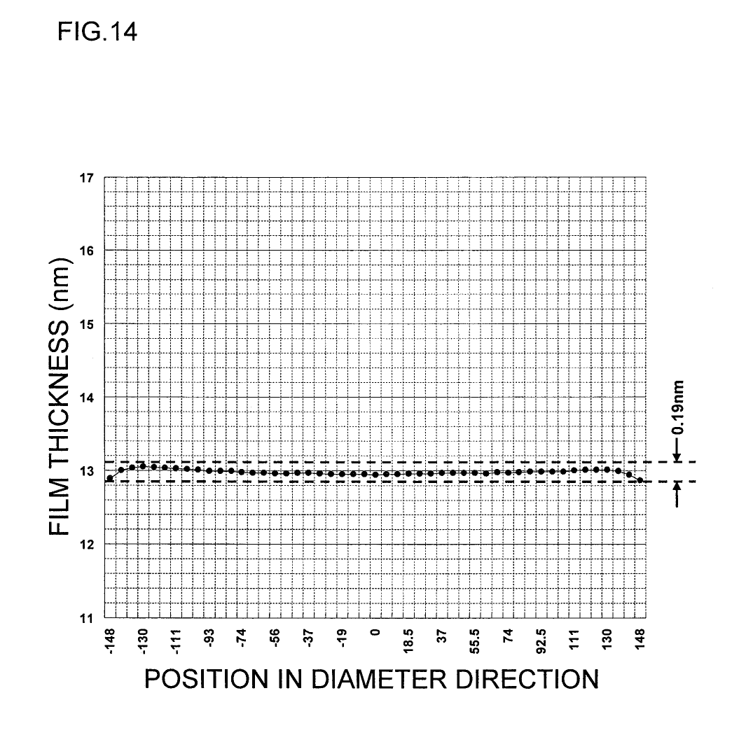

The thickness of thus formed SiRN film (first silicon nitride film) 14b on second semiconductor substrate 15b was measured at 49 points along the diameter of the substrate. FIG. 14 shows measurement results. The variation in the thickness of first silicon nitride film 14b along the diameter of the substrate was 0.19 nm as shown in FIG. 14, which was further smaller than the variation in the thickness in Experiment Example 2. The reason for this is as follows: The second silicon nitride film having a small Si/N ratio and film quality similar to that of the first silicon nitride film was formed in advance on second semiconductor substrate 15b as well as first semiconductor substrates 15a and 15c. Accordingly, the adsorption and consumption of DCS was encouraged on all first semiconductor substrates 15a, 15c and second semiconductor substrate 15b, and excess DCS present in the space between the substrates decreases. As a result, the nonuniformity of the partial pressure of DCS in the space between the substrates becomes smaller, whereby the variation in the film thickness distribution of first silicon nitride film 14b on second semiconductor substrate 15b thus further decreases.

In Experiment Example 3, although an SiN film having optical absorption coefficient k of 0 (Si/N ratio of 0.75) was used as the second silicon nitride film, the second silicon nitride film may alternatively be a silicon nitride film formed of an SiRN film having optical absorption coefficient k greater than 0 but smaller than or equal to 0.20 (Si/N ratio of 0.83). When optical absorption coefficient k falls within the range described above, the variation in the film thickness distribution can be reduced as compared with a case where an SiRN film having a k value ranging from 0.60 to 1.26 is directly formed on the tunnel oxide film. When optical absorption coefficient k is greater than 0.20, the film thickness distribution tends to vary when the second silicon nitride film is formed on the oxide silicon film.

As clearly seen from Experiment Examples 1 to 3, in the stepping film formation process in which a silicon nitride film is formed by using DCS and NH₃ as raw material gases, optical absorption coefficient k, that is, the Si/N ratio can be effectively changed by adjusting the partial pressure at which each of the gases is supplied and the period for which each of the gases is supplied.

In Experiment Example 3, since the front and rear surfaces of all the substrates are coated with the SiN film, which contributes as a DCS consuming material, the variation in the film thickness distribution of the SiRN film is significantly reduced as compared with Experiment Examples 1 and 2. In the example shown in FIGS. 7A and 7B, silicon oxide film 11 is formed on each of the surfaces of not only first semiconductor substrates 15a and 15c but also second semiconductor substrate 15b. These states are therefore the same as the state of a semiconductor substrate on which a tunnel oxide film that forms a component of a flash memory is formed. That is, all semiconductor substrates 15a to 15c have the same configuration as that of semiconductor substrate 15b, which includes a tunnel oxide film formed thereon and is placed in the vertical film formation apparatus. In other words, first semiconductor substrates 15a and 15c which includes the tunnel oxide film and the first and second silicon nitride films formed thereon can also be used as a flash memory as second semiconductor substrate 15b. Therefore, even when each of all the substrates placed in the film formation apparatus includes a tunnel oxide film formed thereon, the variation in the film thickness distribution of the SiRN film can be reduced by forming a silicon nitride film having optical absorption coefficient k ranging from 0 to 0.20 on the tunnel oxide film and forming an SiRN film having optical absorption coefficient k ranging from 0.6 to 1.26 on the silicon nitride film.

According to Experiment Example 3, since the variation in the film thickness distribution of the SiRN film formed on each of the first semiconductor substrates can be reduced, the productivity can be at least doubled.

An SiN film having optical absorption coefficient k of 0 can also be formed using an LPCVD (low-pressure chemical vapor deposition, low-pressure CVD) process. In the formation by an LPCVD process, DCS and ammonia are simultaneously supplied as raw material gases into the film formation chamber for film formation. The film formation conditions can be, for example, set as follows: The temperature is 760° C.; the pressure is 66 Pa, the amount of supplied DCS is 25 sccm; and the amount of supplied ammonia is 500 sccm. In this case, the amount of supplied ammonia (molar quantity) is 20 times the amount of supplied DCS (molar quantity), and the resultant silicon nitride film is made of stoichiometric Si₃N₄.

### Experiment Example 4

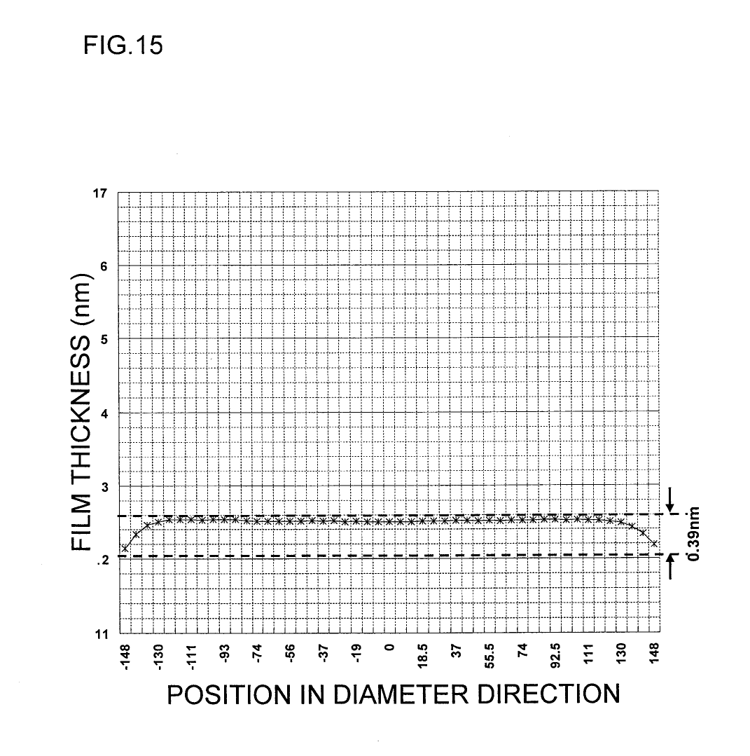

The second and first silicon nitride films were formed in the same manner as in Experiment Example 3 except that the thickness of second silicon nitride film 14a was set at 0.5 nm. The thickness of the thus formed first silicon nitride film on second semiconductor substrate 15b was measured at 49 points along the diameter of the substrate. FIG. 15 shows measurement results. The variation in the thickness of the first silicon nitride film along the diameter of the substrate was 0.39 nm as shown in FIG. 15, which was slightly greater than the variation in Experiment Example 3.

### Experiment Example 5

Semiconductor substrates 15a and 15c and semiconductor substrate 15b were arranged in the vertical direction in the vertical film formation apparatus so that the semiconductor substrate 15b was sandwiched by semiconductor substrates 15a and 15c, and first silicon nitride film 14b was formed. Each of semiconductor substrates 15a and 15c was covered with silicon oxide film 14c instead of silicon nitride film 14c shown in FIG. 6A. The surfaces of the semiconductor substrate 15b were made of exposed silicon. Silicon oxide film 14c was formed to a thickness of 5 nm on the front and rear surfaces of each of semiconductor substrates 15a and 15c using a thermal oxidation process. The thickness of the thus formed silicon nitride film on semiconductor substrate 15b was measured at 49 points along the diameter of the substrate. FIG. 16 shows measurement results. The variation in the thickness of first silicon nitride film 14b along the diameter of the substrate was 1.97 nm, as shown in FIG. 16, which was greater than the variation in any of Experiment Examples described above.

It is apparent that the present invention is not limited to the above embodiments, but may be modified and changed without departing from the scope and spirit of the invention.

The following film formation methods also fall within the scope of the present invention:

1. A method for forming a silicon nitride film, comprising:

forming a second silicon nitride film on a semiconductor substrate; and

forming a first silicon nitride film on the second silicon nitride film using a stepping film formation process in such a way that the first silicon nitride film has optical absorption coefficient k greater than optical absorption coefficient k of the second silicon nitride film and ranging from 0.60 to 1.26.

2. A method for forming a silicon nitride film, comprising:

placing first and second semiconductor substrates in a film formation chamber of a vertical film formation apparatus in such a way that each of the second semiconductor substrates is disposed between two of the first semiconductor substrates in a vertical direction; and

forming a first silicon nitride film having optical absorption coefficient k ranging from 0.6 to 1.26 on the second semiconductor substrate using a stepping film formation process,

wherein each of the first semiconductor substrates includes no silicon oxide film as a film that covers a surface of the first semiconductor substrate when the first silicon nitride film is formed.

3. The method for forming a silicon nitride film according to item 2, further comprising, after placing the first and second semiconductor substrates and before forming the first silicon nitride film:

forming a second silicon nitride film having an optical absorption coefficient smaller than the optical absorption coefficient of the first silicon nitride film on each of the first and second semiconductor substrates.

4. The method for forming a silicon nitride film according to item 1 or 3, further comprising, before forming the second silicon nitride film:

forming a silicon oxide film on each of the semiconductor substrates.

5. The method for forming a silicon nitride film according to any one of items 1, 3, and 4,

wherein a cycle formed of the following steps (a1) to (a4) is carried out at least once in the stepping film formation process:

(a1) supplying a first raw material gas to adsorb silicon onto an object on which a film is formed;

(a2) purging the first raw material gas;

(a3) supplying a second raw material gas to nitride the silicon adsorbed onto the object on which the film is formed into the first silicon nitride film; and

(a4) purging the second raw material gas.

6. The method for forming a silicon nitride film according to item 5,

wherein the first raw material gas is dichlorosilane (SiH₂Cl₂) gas, and the second raw material gas is ammonia (NH₃) gas.

7. The method for forming a silicon nitride film according to item 5 or 6,

wherein a ratio of a molar quantity of the second raw material gas supplied in the (a3) to a molar quantity of the first raw material gas supplied in the (a1), (the molar quantity of the second raw material gas)/(the molar quantity of the first raw material gas), is smaller than 5.

8. The method for forming a silicon nitride film according to any one of items 1 and 3 to 7,

wherein the optical absorption coefficient of the first silicon nitride film ranges from 0.8 to 1.22.

9. The method for forming a silicon nitride film according to any one of items 1 and 3 to 8,

wherein the optical absorption coefficient of the second silicon nitride film ranges from 0 to 0.2.

10. The method for forming a silicon nitride film according to any one of items 1 and 3 to 9,

wherein in forming the second silicon nitride film, the second silicon nitride film is formed using a stepping film formation process in which a cycle formed of the following steps (b1) to (b4) is carried out at least once:

(b1) supplying dichlorosilane (SiH₂Cl₂) gas to adsorb silicon onto an object on which a film is formed;

(b2) purging the dichlorosilane gas;

(b3) supplying ammonia (NH₃) gas to nitride the silicon adsorbed onto the object on which the film is formed to form the second silicon nitride film; and

(b4) purging the ammonia gas.

11. The method for forming a silicon nitride film according to item 10,

wherein a ratio of a molar quantity of the ammonia gas supplied in the (b3) to a molar quantity of the dichlorosilane gas supplied in the (b1), (the molar quantity of the ammonia gas)/(the molar quantity of the dichlorosilane gas), is greater than or equal to 5.

12. The method for forming a silicon nitride film according to any one of items 1 and 3 to 9,

wherein in forming the second silicon nitride film, the second silicon nitride film is formed using a low-pressure CVD process.

13. The method for forming a silicon nitride film according to any one of items 1 and 3 to 12,

wherein a thickness of the second silicon nitride film ranges from 0.1 to 2 nm.

14. A method for manufacturing a nonvolatile storage device, comprising:

forming a tunnel oxide film on a surface of a semiconductor substrate;

forming a second silicon nitride film on a surface of the tunnel oxide film;

forming a first silicon nitride film having optical absorption coefficient k greater than optical absorption coefficient k of the second silicon nitride film and ranging from 0.60 to 1.26 on the second silicon nitride film using a stepping film formation process;

forming a control gate insulating film on the first silicon nitride film;

forming a control gate electrode on the control gate insulating film;

patterning the tunnel oxide film, the second silicon nitride film, the first silicon nitride film, the control gate insulating film, and the control gate electrode; and

forming impurity diffusion layers in the semiconductor substrate on both sides of the control gate electrode.

15. The method for manufacturing a nonvolatile storage device according to item 14,

wherein in the stepping film formation process, a cycle formed of the following steps (a1) to (a4) is carried out at least once:

(a1) supplying a first raw material gas to adsorb the raw material onto an object on which a film is formed;

(a2) purging the first raw material gas;

(a3) supplying a second raw material gas to nitride the raw material adsorbed onto the object on which the film is formed into the first silicon nitride film; and

(a4) purging the second raw material gas.

16. The method for manufacturing a nonvolatile storage device according to item 15,

wherein the first raw material gas is dichlorosilane (SiH₂Cl₂) gas, and the second raw material gas is ammonia (NH₃) gas.

17. The method for manufacturing a nonvolatile storage device according to item 15 or 16,

wherein a ratio of a molar quantity of the second raw material gas supplied in the (a3) to a molar quantity of the first raw material gas supplied in the (a1), (the molar quantity of the second raw material gas)/(the molar quantity of the first raw material gas), is smaller than 5.

18. The method for manufacturing a nonvolatile storage device according to any one of items 14 to 17,

wherein the first silicon nitride film has the optical absorption coefficient ranging from 0.8 to 1.22.

19. The method for manufacturing a nonvolatile storage device according to any one of items 14 to 18,

wherein the second silicon nitride film has the optical absorption coefficient ranging from 0 to 0.2.

20. The method for manufacturing a nonvolatile storage device according to any one of items 14 to 19,

wherein the second silicon nitride film has a thickness ranging from 0.1 to 2 nm.

What is claimed is:

1. A nonvolatile storage device comprising:
a tunnel insulating film disposed on a surface of a semiconductor substrate; and
a charge trap layer disposed in contact with an upper surface of the tunnel insulating film, the charge trap layer including a second charge trap film disposed in contact with the upper surface of the tunnel insulating film and a first charge trap film disposed in contact with an upper surface of the second charge trap film.

2. The nonvolatile storage device according to claim 1, further comprising:
a control gate insulating film disposed in contact with an upper surface of the first charge trap film;
a control gate electrode disposed in contact with an upper surface of the control gate insulating film; and
a first metal silicide film disposed in contact with an upper surface of the control gate electrode.

3. The nonvolatile storage device according to claim 2,
wherein the second charge trap film is formed of a second silicon nitride film, and
the first charge trap film is formed of a first silicon nitride film.

4. The nonvolatile storage device according to claim 3,
wherein an optical absorption coefficient of the second silicon nitride film derived from spectroscopic ellipsometry is smaller than an optical absorption coefficient of the first silicon nitride film derived from spectroscopic ellipsometry.

5. The nonvolatile storage device according to claim 3,
wherein an optical absorption coefficient of the second silicon nitride film derived from spectroscopic ellipsometry ranges from 0 to 0.20, and
an optical absorption coefficient of the first silicon nitride film derived from spectroscopic ellipsometry ranges from 0.6 to 1.26.

6. The nonvolatile storage device according to claim 1,
wherein the second charge trap film has a thickness ranging from 0.1 to 2.0 nm, and
the first charge trap film has a thickness ranging from 12 to 15 nm.

7. The nonvolatile storage device according to claim 1,
wherein the tunnel insulating film is formed of a silicon oxide film having a thickness ranging from 0.5 to 2.0 nm.

8. The nonvolatile storage device according to claim 2,
wherein the control gate insulating film is formed of a silicon oxide film having a thickness ranging from 3.0 to 7.0 nm.

9. The nonvolatile storage device according to claim 2,
wherein the tunnel insulating film (O), the charge trap layer (N) including the second charge trap film and the first charge trap film, the control gate insulating film (O), the first metal silicide film, and the control gate electrode (S) form a SONO structure, and
a sidewall of the SONO structure is covered with a sidewall insulating film.

10. The nonvolatile storage device according to claim 9, further comprising:
an isolation region provided in the semiconductor substrate; and
a plurality of active regions surrounded by the isolation region, the active regions extending in a first direction and being arranged and aligned in a second direction perpendicular to the first direction,
wherein the nonvolatile storage device comprises a plurality of the SONO structures each of which is arranged and aligned in the first direction on each of the active regions.

11. The nonvolatile storage device according to claim 10,
wherein an impurity diffusion layer is provided in a surface of each of the active regions between the SONO structures adjacent in the first direction, and
a second metal silicide film is further provided on an upper surface of the impurity diffusion layer.

12. The nonvolatile storage device according to claim 11, further comprising
an interlayer insulating film that covers the SONO structures,
wherein a bit-line contact plug is connected to the upper surface of the impurity diffusion layer located at one end of each of the active regions, in order to penetrate through the interlayer insulating film.

13. The nonvolatile storage device according to claim 12, further comprising:
a bit line connected to an upper surface of the bit-line contact plug, the bit line being disposed on the interlayer insulating film and extending in the first direction.
